(19) United States
(12) Patent Application Publication
(10) Pub. No.: US 2026/0164890 A1
(43) Pub. Date: Jun. 11, 2026

(54) ELECTRONIC DEVICE

(71) Applicant: Innolux Corporation, Miaoli County (TW)

(72) Inventors: Shun-Yuan Hu, Miaoli County (TW); Jia-Huei Lin, Miaoli County (TW)

(73) Assignee: Innolux Corporation, Miaoli County (TW)

(21) Appl. No.: 19/390,681

(22) Filed: Nov. 17, 2025

Related U.S. Application Data
(60) Provisional application No. 63/729,964, filed on Dec. 10, 2024.

(30) Foreign Application Priority Data
Jun. 26, 2025 (CN) 202510872396.7

(51) Int. Cl. H10H 29/49

(52) U.S. Cl. CPC H10H 29/49

(57) ABSTRACT

Provided is an electronic device, which includes a substrate, a first electronic component, a second electronic component, a first switch element, a wire, and a first conductive pad. The first electronic component and the second electronic component are disposed on the substrate. The first switch element is disposed on the substrate. The wire is disposed on the substrate. The first conductive pad is disposed on the substrate. The first switch element is electrically connected to the first electronic component and the second electronic component through the wire and the first conductive pad.

### CROSS-REFERENCE TO RELATED APPLICATION

This application claims the priority benefit of U.S. provisional application Ser. No. 63/729,964, filed on Dec. 10, 2024 and China application serial no. 202510872396.7, filed on Jun. 26, 2025. The entirety of each of the above-mentioned patent applications is hereby incorporated by reference herein and made a part of this specification.

### BACKGROUND

### Technical Field

The disclosure relates to an electronic device.

### Related Art

An electronic device driven by active-matrix addressing includes multiple switch elements disposed on a substrate. The switch elements are configured to drive corresponding electronic components. However, if at least one of the switch elements is damaged, it may be difficult to perform repair. If the electronic component is a light emitting element, a dark spot may be generated due to the damage switch element, causing the display quality to decline.

### SUMMARY

The disclosure relates to an electronic device, which has relatively good display quality.

Some embodiments of the disclosure provide an electronic device, which includes a substrate, a first electronic component, a second electronic component, a first switch element, a wire, and a first conductive pad. The first electronic component and the second electronic component are disposed on the substrate. The first switch element is disposed on the substrate. The wire is disposed on the substrate. The first conductive pad is disposed on the substrate. The first switch element is electrically connected to the first electronic component and the second electronic component through the wire and the first conductive pad.

In order to make the features and advantages of the disclosure more comprehensible, the following examples are given and described in detail with the accompanying drawings as follows.

### BRIEF DESCRIPTION OF THE DRAWINGS

FIGS. 1 to 6 respectively are a schematic partial top view of an electronic device according to some embodiments of the disclosure.

FIG. 7A to FIG. 7E are schematic partial top views of a conductive pad according to some embodiments of the disclosure.

### DESCRIPTION OF THE EMBODIMENTS

Reference will now be made in detail to the exemplary embodiments of the disclosure. Examples of the exemplary embodiments are illustrated in the drawings, and the same reference numerals can be used in the drawings and the description to refer to the same or similar parts.

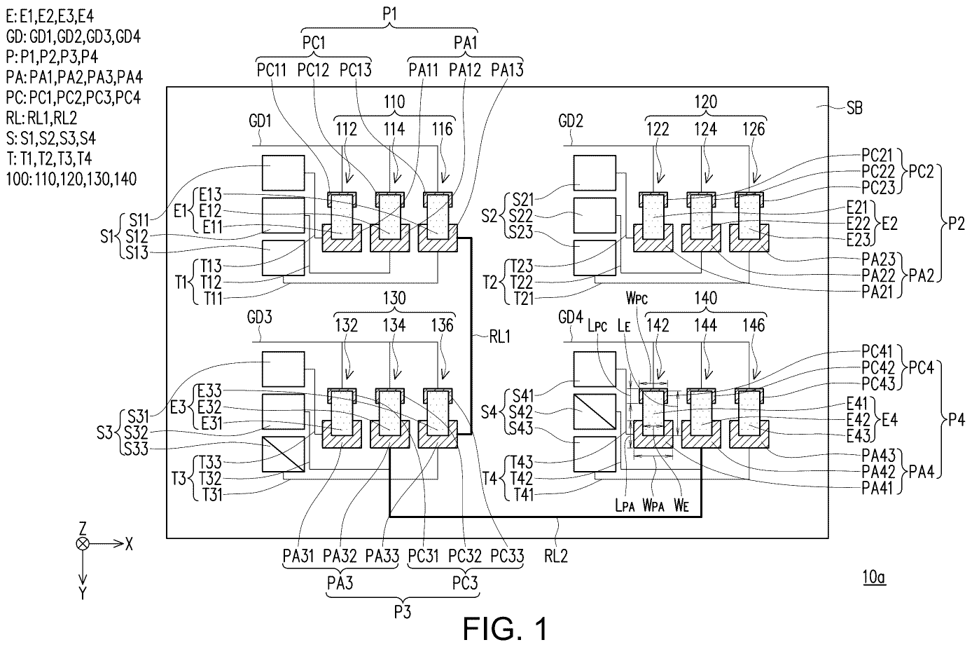

In the embodiment shown in FIG. 1, an electronic device 10a has multiple pixels 100, and one of the multiple pixels 100 includes multiple subpixels that emit different colors of light.

In detail, please refer to FIG. 1. FIG. 1 shows that the multiple pixels 100 in the electronic device 10a include a pixel 110, a pixel 120, a pixel 130, and a pixel 140. The pixel 110 includes a subpixel 112, a subpixel 114 and a subpixel 116. The pixel 120 includes a subpixel 122, a subpixel 124 and a subpixel 126. The pixel 130 includes a subpixel 132, a subpixel 134 and a subpixel 136. The pixel 140 includes a subpixel 142, a subpixel 144 and a subpixel 146.

From another perspective, in the embodiment, the electronic device 10a includes a substrate SB, an electronic component E, a switch element S, and a conductive pad P.

The electronic component E is disposed on the substrate SB. In some embodiments, the electronic component includes a light emitting element. The electronic component E may be a light emitting diode (LED), including, for example, an organic light emitting diode (OLED), a micro light emitting diode (micro LED), a mini light emitting diode (mini LED), or a quantum dot (QD) light emitting diode, fluorescence, phosphor, or other appropriate materials.

In the embodiment, the electronic component E includes an electronic component E1, an electronic component E2, an electronic component E3 and an electronic component E4 respectively located in the pixels 110 to 140. The electronic components E1 to E4 respectively include electronic components E11 to E13, electronic components E21 to E23, electronic components E31 to E33 and electronic components E41 to E43 corresponding to the corresponding subpixels. When the electronic component E includes a light emitting element, the electronic component E11 to the electronic component E13 emit different light from each other. For example, the electronic component E11 emits red light, the electronic component E12 emits green light, and the electronic component E13 emits blue light. Similarly, the electronic components E21 to E23, the electronic components E31 to E33, and the electronic components E41 to E43 also emit different colors of light from each other. In the embodiment, the electronic component E located in the different pixels 100 may emit light of the same color.

In the embodiment, the electronic component E may include a width W_{E} in a direction X and a length L_{E} in a direction Y. For example, FIG. 1 shows that the electronic component E43 includes the width W_{E} in the direction X and the length L_{E} in the direction Y.

The switch element S is disposed on the substrate SB. In some embodiments, the switch element S includes a thin film transistor. The switch element S may be electrically connected to the electronic component E to provide a corresponding signal to the electronic component E.

In the embodiment, the switch element S includes a switch element S1, a switch element S2, a switch element S3 and a switch element S4 respectively located in the pixels 110 to 140. The switch elements S1 to S4 respectively include switch elements S11 to S13, switch elements S21 to S23, switch elements S31 to S33, and switch elements S41 to S43 that are electrically connected to the corresponding electronic components E11 to E13, the electronic components E21 to E23, the electronic components E31 to E33, and the electronic components E41 to E43. Taking the switch element S1 as an example, a drain of the switch element S11 is electrically connected to an anode end of the electronic component E11 through a trace T11 in a trace T1. A drain of the switch element S12 is electrically connected to an anode end of the electronic component E12 through a trace T12 in the trace T1. A drain of the switch element S13 is electrically connected to an anode end of the electronic component E13 through a trace T13 in the trace T1. Similarly, the switch elements S21 to S23, the switch elements S31 to S33, and the switch elements S41 to S43 are respectively electrically connected to an anode end of the electronic components E21 to E23, the electronic components E31 to E33, and the electronic components E41 to E43 through traces T21 to T23, traces T31 to T33, and traces T41 to T43.

The conductive pad P is disposed on the substrate SB. In the embodiment, the conductive pad P includes a conductive pad PA and a conductive pad PC separated from each other and arranged along the direction Y. The conductive pad P is electrically connected to the corresponding electronic component E, and at least partially overlaps with the corresponding electronic component E in the direction Z.

In the embodiment, the conductive pad PA includes a conductive pad PA1, a conductive pad PA2, a conductive pad PA3 and a conductive pad PA4 respectively located in the pixels 110 to 140. The conductive pads PA1 to PA4 respectively include conductive pads PA11 to PA13, conductive pads PA21 to PA23, conductive pads PA31 to PA33, and conductive pads PA41 to PA43 electrically connected to the corresponding electronic components E11 to E13, the electronic components E21 to E23, the electronic components E31 to E33 and the electronic components E41 to E43. Briefly, the conductive pad PA may be adjacent to the electronic component E and serve as an anode pad to be electrically connected to the anode end of the electronic component E.

Two outermost sides of the conductive pad PA are greater than two outermost sides of the electronic component E in the direction X. Two outermost sides of the conductive pad PA are greater than one outermost side of the electronic component E in the direction Y.

The conductive pad PA includes a width W_{PA} in the direction X and a length L_{PA} in the direction Y. In some embodiments, the width W_{PA} is greater than the width W_{E}, and/or the length L_{PA} is greater than the length L_{E}. In the embodiment, the width W_{PA} is greater than the width W_{E}. A difference between the width W_{PA} and the width W_{E} is greater than or equal to 1 micron and less than or equal to 50 microns. In addition, in the embodiment, the length L_{PA} is greater than the length L_{E}. A difference between the length L_{PA} and the length L_{E} is greater than or equal to 1 micron and less than or equal to 50 microns.

In the embodiment, the electronic device 10a further includes a ground line GD. One ground line GD is electrically connected to the conductive pad PC located in one pixel 100, so that the electronic component E located in the one pixel 100 has a common cathode. In detail, the ground line GD includes a ground line GD1, a ground line GD2, a ground line GD3 and a ground line GD4. The ground lines GD1 to GD4 are respectively electrically connected to a conductive pad PC1, a conductive pad PC2, a conductive pad PC3 and a conductive pad PC4 located in the pixels 110 to 140. In the embodiment, the conductive pads PC1 to PC4 respectively include conductive pads PC11 to PC13, conductive pads PC21 to PC23, conductive pads PC31 to PC33, and conductive pads PC41 to PC43 electrically connected to the corresponding electronic components E11 to E13, the electronic components E21 to E23, the electronic components E31 to E33, and the electronic components E41 to E43. Briefly, the conductive pad PC serves as a cathode pad and is electrically connected to a cathode end of the electronic component E.

The conductive pad PC includes a width W_{PC} in the direction X and a length L_{PC} in the direction Y. In some embodiments, the width W_{PA} is greater than the width W_{PC}, and/or the length L_{PA} is greater than the length L_{PC}. In the embodiment, the width W_{PA} is greater than the width W_{PC}, and the length L_{PA} is greater than the length L_{PC}. A difference between the width W_{PA} and the width W_{PC} (the length L_{PA} and the length L_{PC}) is greater than or equal to 1 micron and less than or equal to 50 microns.

In FIG. 1, the electronic device 10a further includes a wire RL1 and a wire RL2. When the switch element S33 located in the pixel 130 and the switch element S42 located in the pixel 140 have defects, the trace T31 or the trace T42 may first be cut off to avoid electrical properties being affected by the abnormal switch element S33 or the abnormal switch element S42 after the wire RL1 or the wire RL2 is electrically connected to the conductive pad PA33 or the conductive pad PA42. In the embodiment, in order to allow the electronic component E33 electrically connected to the defective switch element S33 to be driven, the other end of the wire RL1 may be electrically connected to another switch element S13. The other switch element S13 drives the light emitting element E13 and the electronic component E33 to emit a same light. In order to allow the electronic component E42 electrically connected to the defective switch element S42 to be driven, the other end of the wire RL2 may be electrically connected to another switch element S32. The other switch element S32 drives the light emitting element E42 and the electronic component E32 to emit a same light. Taking the electronic device 10a shown in FIG. 1 as an example, the other end of the wire RL1 may be electrically connected to the switch element S13 through the conductive pad PA13, so that the electronic component E33 may be driven by the switch element S13 through the wire RL1. Similarly, in order to allow the electronic component E42 electrically connected to the defective switch element S42 to be driven, the other end of the wire RL2 may be electrically connected to the switch element S32 through the conductive pad PA32, so that the electronic component E42 may be driven by the switch element S32 through the wire RL2. It is worth noting that the trace T31 configured to electrically connect the switch element S33 and the electronic component E33, and the trace T42 configured to electrically connect the switch element S42 and the electronic component E42 may be respectively cut off to decrease the possibility of at least one of the switch element S33 and the switch element S42 affecting at least one of the electronic component E33 and the electronic component E42. In the embodiment, one end of the wire RL1 is connected to the conductive pad PA13, and the other end of the wire RL1 is connected to the conductive pad PA33. The conductive pad PA13 corresponds to the pixel 110, and the conductive pad PA33 corresponds to the pixel 130. The pixel 110 and the pixel 130 are adjacently disposed. In the embodiment, one end of the wire RL2 is connected to the conductive pad PA32, and the other end of the wire RL2 is connected to the conductive pad PA42. The conductive pad PA32 corresponds to the pixel 130, and the conductive pad PA42 corresponds to the pixel 140. The pixel 130 and the pixel 140 are adjacently disposed.

In some embodiments, electrical inspection may be performed on the electronic component E to detect whether a defective point exists in the pixel 100. For example, electrical inspection may be performed on the electronic component E using an open/short test (O/S test), so that the electronic component E emits light to confirm the quality of the emitted light. After it is confirmed that certain electronic components E may not emit light or the quality of the emitted light is poor, it may be further confirmed whether it is a problem with the electronic component E itself or the switch element S electrically connected thereto having defects. After it is confirmed that the switch element S has defects, the process in the above embodiments may be performed to form the corresponding wire RL, so that the electronic component E that originally could not emit light or had poor quality of the emitted light may be driven again by another switch element S.

In the embodiment, the difference between the width W_{PA} and the width W_{E} is designed to be greater than or equal to 1 micron and less than or equal to 50 microns. Alternatively, the difference between the width W_{PA} and the width W_{PC} is designed to be greater than or equal to 1 micron and less than or equal to 50 microns. Through this design, the conductive pad PA has a relatively large dimension and has a sufficient portion configured to be electrically connected to the corresponding wire RL, so that the conductive pad PA may have a repair function. In some embodiments, the wire RL1 and the wire RL2 may not be on the same layer.

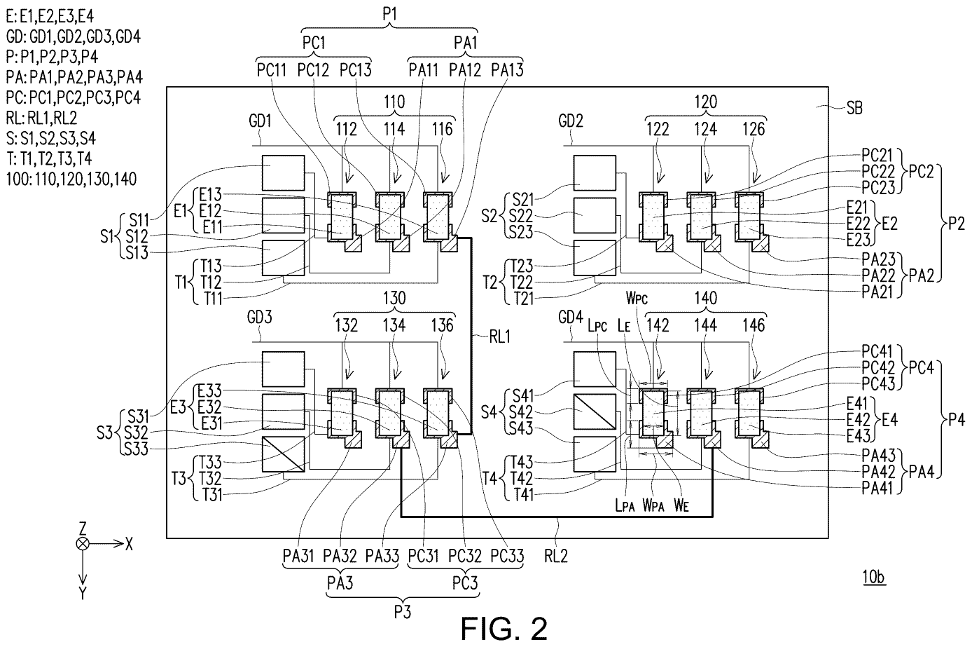

Please refer to FIG. 2, the main difference between an electronic device 10b and the electronic device 10a is that: the conductive pad PA has a special-shaped structure. At least one outermost side of the conductive pad PA is greater than one outermost side of the electronic component E in the direction X and the direction Y.

In the top view of electronic device 10b, the conductive pad PA may include a rectangular structure and a compensation structure located at a lower right of the rectangular structure. The rectangular structure contacts the compensation structure in the direction X and the direction Y. A dimension of the compensation structure is smaller than a dimension of the rectangular structure.

Based on this, through the foregoing design, a dimension of the conductive pad PA may be reduced. The compensation structure of the conductive pad PA may be configured to be electrically connected to the corresponding wire RL, so that the conductive pad PA has a repair function. In some embodiments, the wire RL1 and the wire RL2 may not be on the same layer.

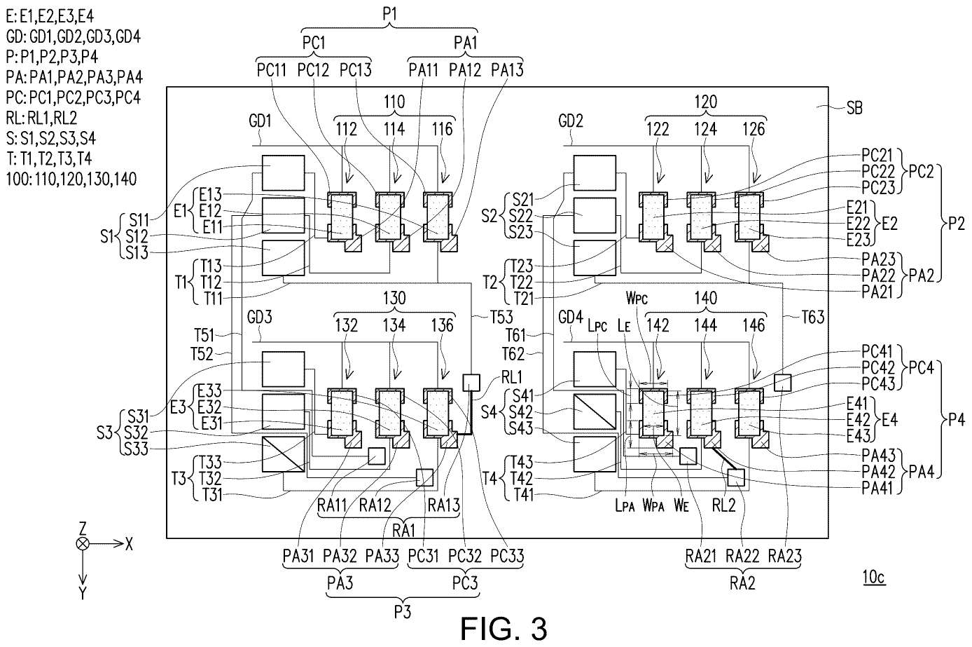

Please refer to FIG. 3. The main difference between an electronic device 10c and the electronic device 10b is that: the electronic device 10c further includes a repair pad RA. In two adjacent pixels 100, two switch element S configured to drive the electronic component E that emit a same color are electrically connected to each other.

In the embodiment, the repair pad RA may include a repair pad RA1 and a repair pad RA2. The repair pad RA1 is electrically connected to the pixel 110 and the pixel 130 that are adjacent in the direction Y. The repair pad RA2 is electrically connected to the pixel 120 and the pixel 140 that are adjacent in the direction Y.

In detail, the repair pad RA1 includes a repair pad RA11, a repair pad RA12 and a repair pad RA13. The repair pads RA11 to RA13 are electrically connected to the switch elements S11 to S13 through traces T51 to T53, respectively. Similarly, the repair pad RA2 includes a repair pad RA21, a repair pad RA22 and a repair pad RA23 electrically connected to the switch elements S21 to S23 through traces T61 to T63. The repair pads RA11 to RA13 are all located in the same pixel 130, and the repair pads RA21 to RA23 are all located in the same pixel 140.

In the embodiment, the switch element S33 and the switch element S42 are confirmed to have defects, so the wire RL1 and the wire RL2 may be formed. One end of the wire RL1 is connected to the conductive pad PA33, and the other end of the wire RL1 is connected to the repair pad RA13. In addition, one end of the wire RL2 is connected to the conductive pad PA42, and the other end of the wire RL2 is connected to the repair pad RA22. In some embodiments, the wire RL1 and the wire RL2 may not be on the same layer.

Based on this, through the foregoing design, a length of the wire RL may be relatively reduced, which can improve the convenience of the process.

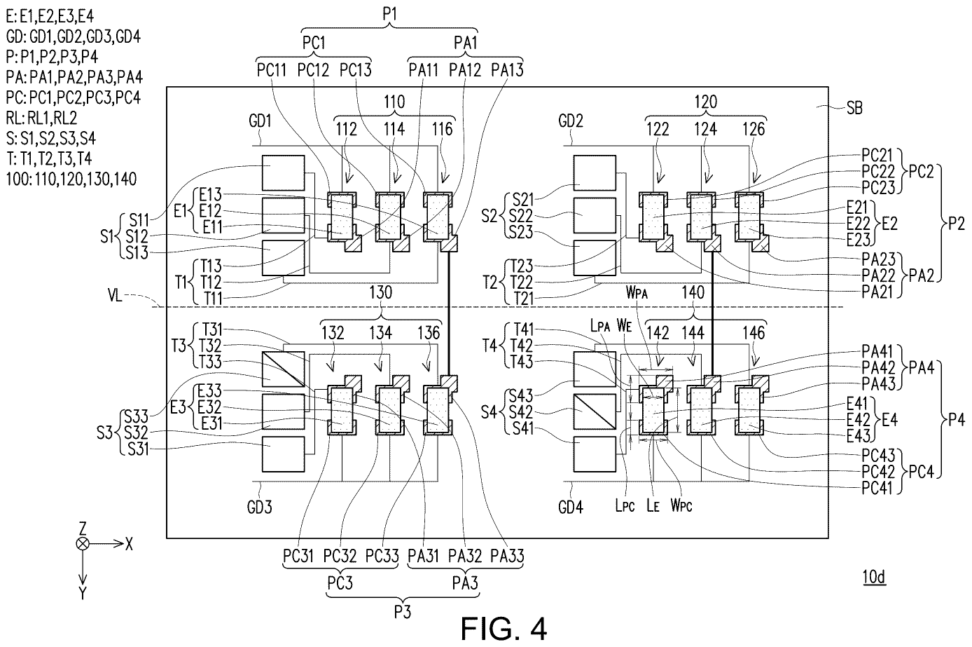

Please refer to FIG. 4. The main difference between an electronic device 10d and the electronic device 10b is that two adjacent pixels 100 are in a mirror relationship with each other.

In the embodiment, the pixel 110 and the pixel 130 that are adjacent in the direction Y are in a mirror relationship with each other. The pixel 120 and the pixel 140 that are adjacent in the direction Y are in a mirror relationship with each other. In detail, FIG. 4 shows a virtual line VL extending along the direction X, so that the pixel 110 and the pixel 130, and the pixel 120 and the pixel 140 form a mirror relationship with the virtual line VL. In some embodiments, the wire RL1 and the wire RL2 may not be on the same layer.

Based on this, through the foregoing design, a distance between the conductive pads PA in the two adjacent pixels 100 may be decreased, so that a length of the wire RL may be relatively reduced, which can improve the convenience of the process.

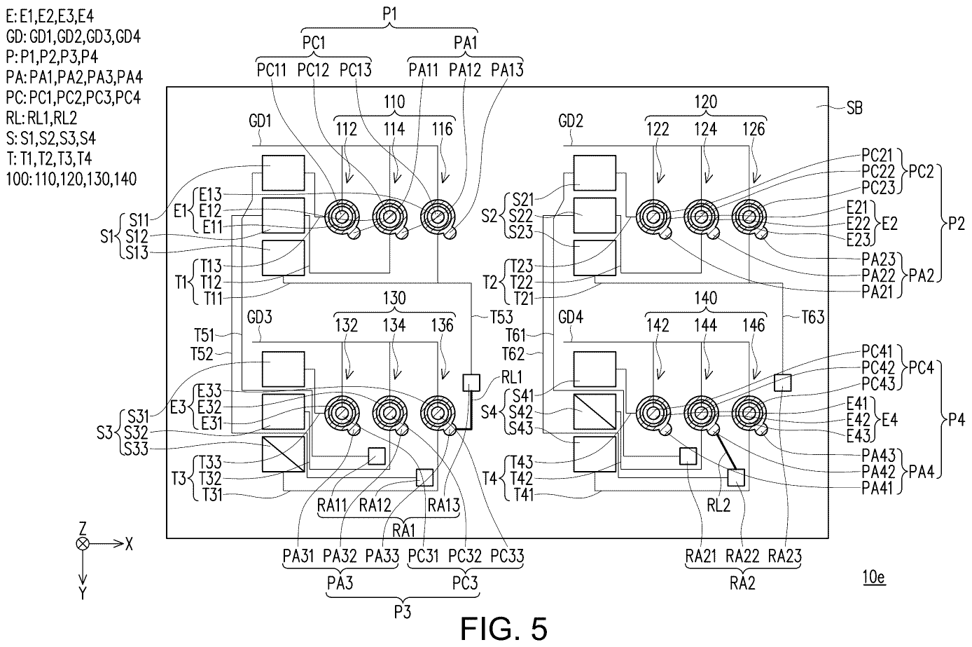

Please refer to FIG. 5. The main difference between an electronic device 10e and the electronic device 10c is that: in the top view of the electronic device 10e, the electronic component E and the conductive pad PC have a circular structure. The conductive pad PA has a special-shaped structure, which includes an annular structure and a circular structure.

In the embodiment, the electronic component E overlaps with the conductive pad PC to be electrically connected to each other. The electronic component E at least partially overlaps with the conductive pad PA to be electrically connected to each other. The electronic component E does not overlap with the circular structure of the conductive pad PA. In some embodiments, the wire RL1 and the wire RL2 may not be on the same layer.

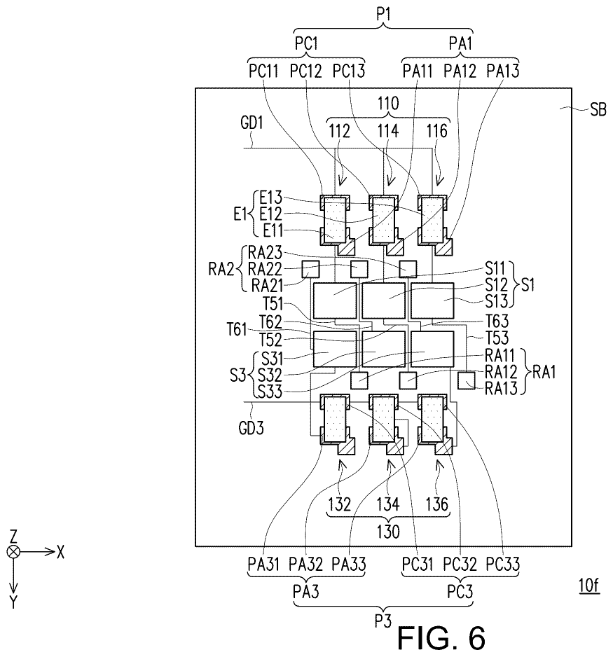

Please refer to FIG. 6. The main differences between an electronic device 10f and the electronic device 10b are: (1) the electronic device 10f further includes the repair pad RA; (2) in two adjacent pixels 100, two switch elements S configured to drive the electronic components E that emit a same color are close to each other and are in a mirror relationship with each other.

In the embodiment, the repair pad RA may include the repair pads RA1 and RA2. The repair pad RA1 is located in the pixel 130 and is electrically connected to the switch element S in the pixel 110. The repair pad RA2 is located in the pixel 110 and is electrically connected to the switch element S in the pixel 130.

In detail, the repair pad RA1 includes the repair pads RA11 to RA13 electrically connected to the switch elements S11 to S13 through the trace T51, respectively. Similarly, the repair pad RA2 includes the repair pads RA21 to RA23 electrically connected to the switch elements S31 to S33 through the traces T61 to T63. The repair pads RA11 to RA13 are all located in the same pixel 130, and the repair pads RA21 to RA23 are all located in the same pixel 140.

Based on this, through the foregoing design, a length of the wire RL may be relatively reduced, which can improve the convenience of the process.

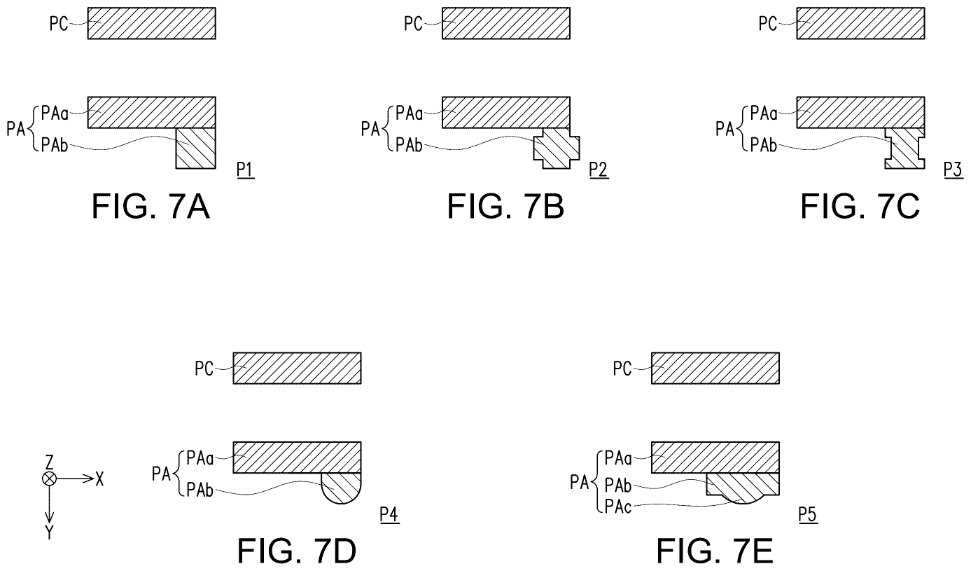

In the embodiments shown in FIG. 7A to FIG. 7E, the conductive pad may include a first structure and a second structure. The first structure may include a rectangular structure. The second structure may include a rectangular structure, a circular structure, a semicircular structure, a cross-shaped structure, an I-type structure, or a combination thereof. In FIG. 7A to FIG. 7E, conductive pads P1 to P5 respectively include the conductive pad PA and the conductive pad PC.

Please refer to FIG. 7A. The conductive pad PA has a special-shaped structure, including a rectangular structure PAa and a rectangular structure PAb contacting the rectangular structure PAa in the direction Y. A dimension of the rectangular structure PAb is smaller than a dimension of the rectangular structure PAa.

Please refer to FIG. 7B. The conductive pad PA has a special-shaped structure, including the rectangular structure PAa and a cross-shaped structure PAb contacting the rectangular structure PAa in the direction Y. A dimension of the cross-shaped structure PAb is smaller than a dimension of the rectangular structure PAa.

Please refer to FIG. 7C. The conductive pad PA has a special-shaped structure, including the rectangular structure PAa and an I-shaped structure PAb contacting the rectangular structure PAa in the direction Y. A dimension of the I-shaped structure PAb is smaller than a dimension of the rectangular structure PAa.

Please refer to FIG. 7D. The conductive pad PA has a special-shaped structure including the rectangular structure PAa and a semicircular structure PAb contacting the rectangular structure PAa in the direction Y. A dimension of the semicircular structure PAb is smaller than a dimension of the rectangular structure PAa.

Please refer to FIG. 7E. The conductive pad PA has a special-shaped structure including the rectangular structure PAa, a rectangular structure PAb contacting the rectangular structure PAa in the direction Y, and a semicircular structure PAc contacting the rectangular structure PAb in the direction Y. A dimension of a combination of the rectangular structure PAb and the semicircular structure PAc is smaller than a dimension of the rectangular structure PAa.

In summary, when at least one of the multiple switch elements disposed on the substrate is damaged such that the corresponding electronic component may not be driven, the normally functioning switch element may be electrically connected to the electronic component through the wire being formed to perform repair. Therefore, when the electronic component is a light emitting element, a dark spot may not be generated due to damage of the corresponding switch element, thereby enhancing the display quality of the electronic device.

Furthermore, in the electronic device provided by other embodiments of the disclosure, in one direction, at least one outermost side of the anode pad (or the cathode pad) is designed to be greater than an outermost side of the electronic component. The wire may be formed on the substrate by a relatively simple manufacturing process, so that the wire is electrically connected to the anode pad, thereby enabling the normally functioning switch element to be electrically connected to the electronic component through the wire and the anode pad.

What is claimed is:

1. An electronic device, comprising:
a substrate;
a first electronic component and a second electronic component, disposed on the substrate;
a first switch element, disposed on the substrate;
a wire, disposed on the substrate; and
a first conductive pad, disposed on the substrate,
wherein the first switch element is electrically connected to the first electronic component and the second electronic component through the wire and the first conductive pad.

2. The electronic device according to claim 1, wherein the first electronic component and the second electronic component are light emitting elements of a same color.

3. The electronic device according to claim 1, wherein the first conductive pad is at least adjacent to at least one of the first electronic component and the second electronic component.

4. The electronic device according to claim 1, further comprising:
a second conductive pad, disposed on the substrate,
wherein one end of the wire is connected to the first conductive pad, and the other end of the wire is connected to the second conductive pad.

5. The electronic device according to claim 4, wherein the wire is not on a same layer or not on a same horizontal plane with at least one trace.

6. The electronic device according to claim 1, wherein at least one outermost side of the first conductive pad in a first direction is greater than an outermost side of the first electronic component in the first direction; or wherein at least one outermost side of the first conductive pad in a second direction is greater than an outermost side of the first electronic component in the second direction.

7. The electronic device according to claim 1, wherein a difference between a width of the first conductive pad in a first direction and a width of the first electronic component in the first direction is greater than or equal to 1 micron and less than or equal to 50 microns.

8. The electronic device according to claim 1, wherein a length of the first conductive pad in a second direction is greater than a length of the first electronic component in the second direction.

9. The electronic device according to claim 8, wherein a difference between the length of the first conductive pad in the second direction and the length of the first electronic component in the second direction is greater than or equal to 1 micron and less than or equal to 50 microns.

10. The electronic device according to claim 1, further comprising:
a third conductive pad, disposed on the substrate, and electrically connected to the first electronic component; and
a ground line, electrically connected to the first electronic component through the third conductive pad.

11. The electronic device according to claim 4, wherein the first conductive pad corresponds to one pixel and the second conductive pad corresponds to another pixel, wherein the pixel and the other pixel are adjacently disposed.

12. The electronic device according to claim 10, wherein a length of the first conductive pad in a second direction is greater than a length of the third conductive pad in the second direction.

13. The electronic device according to claim 12, wherein a difference between the length of the first conductive pad in the second direction and the length of the third conductive pad in the second direction is greater than or equal to 1 micron and less than or equal to 50 microns.

14. The electronic device according to claim 1, further comprising:
a first pixel, wherein the first electronic component is located in the first pixel; and
a second pixel, wherein the second electronic component is located in the second pixel.

15. The electronic device according to claim 14, wherein the first pixel and the second pixel are in a mirror relationship with a virtual line extending in a first direction as a reference.

16. The electronic device according to claim 1, wherein the first conductive pad has a special-shaped structure.

17. The electronic device according to claim 16, wherein the first conductive pad comprises a first structure and a second structure, wherein the second structure contacts the first structure in at least one of a first direction and a second direction, and a dimension of the second structure is smaller than a dimension of the first structure.

18. The electronic device according to claim 17, wherein the first structure comprises a rectangular structure.

19. The electronic device according to claim 17, wherein the first structure comprises an annular structure.

20. The electronic device according to claim 17, wherein the second structure comprises a rectangular structure, a circular structure, a semicircular structure, a cross-shaped structure, an I-type structure, or a combination thereof.
